(19) United States
(12) Patent Application Publication
(10) Pub. No.: US 2008/0164929 A1
(43) Pub. Date: Jul. 10, 2008

(54) Electronic Circuit Wherein an Asynchronous Delay is Realized

(75) Inventors: Jozef Laurentius Wilhelmus Kessels, Eindhoven (NL); Adrianus Marinus Gerardus Peeters, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/908,966

(22) PCT Filed: Mar. 15, 2006
(86) PCT No.: PCT/IB2006/050805

§ 371 Date: Sep. 18, 2007

(30) Foreign Application Priority Data
Mar. 22, 2005 (EP) 05102274.7

(51) Int. Cl. H03H 11/26

(52) U.S. Cl. 327/261

(57) ABSTRACT

The electronic circuit contains a basic delay circuit (14). A delay is realized by activating the same basic delay circuit (14) a plurality of times in response to a single start signal before generating a response to that start signal. A control circuit (12) receives a start signal and an outputs a response. The control circuit (12) causes a series of signals to be passed through the delay circuit (14), the series starting at a time that is time-continuously triggered by the start signal. Each successive signal in the series starts after a preceding signal has emerged from the delay circuit (12) and the series being terminated after a controlled number of more than one signal has been passed. The control circuit (12) supplies the response upon termination of the series. In one embodiment the series is realized by means of a handshake sequencing circuit (120) that generates a series of successive handshake transactions.

The invention relates to a circuit wherein asynchronous delays are realized.

A delay circuit is described in a publication titled “On-chip timing reference for self-timed microprocessor”, by S. Temple and S. B. Furber, and published in Electronics Letters May 2000, (vol 36 No 11) pages 942 and 943. This circuit contains a chain of delay elements and associate multiplexers that make it possible to select the amount of delay between signals at the input and signals at the output.

Each delay element typically contains a chain of inverter circuits, wherein the delay time is realized by the time needed to charge node capacitances through resistive output impedances of the inverters. The required number of inverters is proportional to the delay. This means that a large circuit is required if a large delay is required.

An alternative method to realize large delays is to use a synchronous circuit with a counter that counts a predetermined number of clock pulses to realize a delay. But in this way only a synchronous delay is possible, which starts and ends at time-points that are defined by a clock, not an asynchronous delay that can start and end at any time point.

Among others, it is an object of the invention to provide for a circuit wherein asynchronous delays are realized wherein the size of the circuits that is required to realize the delay increases less with the delay.

The invention provides for an electronic circuit according to Claim 1. The electronic circuit realizes a time-continuously delayed response to a start signal. As used herein, “time-continuously” means absence of limitations to discrete time points (as defined by an independent clock), so that any change in the timing of the start point causes a corresponding equal change in the response. The delay is realized by activating the same basic delay circuit a plurality of times in response to a single start signal before generating a response to that start signal. When the single start signal starts the circuit sends a series of signals to the basic delay circuit, each successive signal in the series starting after a preceding signal has emerged from the basic delay circuit. After a controlled number of signals has been passed through the basic delay circuit the delayed response is generated. The series of signals is terminated after the controlled number of signals, so that the circuit is subsequently able to accept a next signal after a time-continuous period, independent of timing of the previous signal.

Preferably, the circuit is constructed so that it responds symmetrically (with the same delay) to transitions of mutually opposite polarity in the start signal, each time by causing a same series of signals through the basic delay circuit.

In an embodiment the series of signals is generated by means of an asynchronous sequencer circuit. The sequencer starts the first handshake at a first handshake interface started in response to the start signal. Successive handshakes at successive sequenced handshake interfaces are started each in response to completion of a handshake at a preceding one of the sequenced handshake interfaces. A handshake multiplexer routes the starts all of these handshakes to the same basic delay circuit, which acknowledges each handshake after a delay, determined by the delay circuit.

A chain of such combinations of sequencing circuit-handshake multiplexers may be used in front of the basic delay circuit. This makes it possible to realize a delay that increases exponentially as a function of the number of combinations.

As an alternative, the delay circuit may be incorporated in an oscillator loop that also contains an enable circuit, which is controlled by a control circuit that temporarily enables the loop until the oscillator loop has generated a predetermined number of signals.

In an embodiment the circuit is arranged to program the number of signals that is passed though the delay circuit before the circuit responds to the start signal. Programming can be effected in various ways. For example in the designs based on the sequencer by selectably (under control of programmed information) bypassing one or more of the combinations of sequencing circuit-handshake multiplexers. As another example, programming can be effected by selectably (under control of programmed information) “short-circuiting” part of the sequenced handshake interfaces, i.e. by acknowledging handshakes at these selected interfaces without waiting the delay through the delay circuit. In the designs based on an oscillator loop counter the number of signal can be programmed for example by using a programmable counter.

These and other objects and advantageous aspects of the invention will be illustrated by means of non-limitative examples using the following figures.

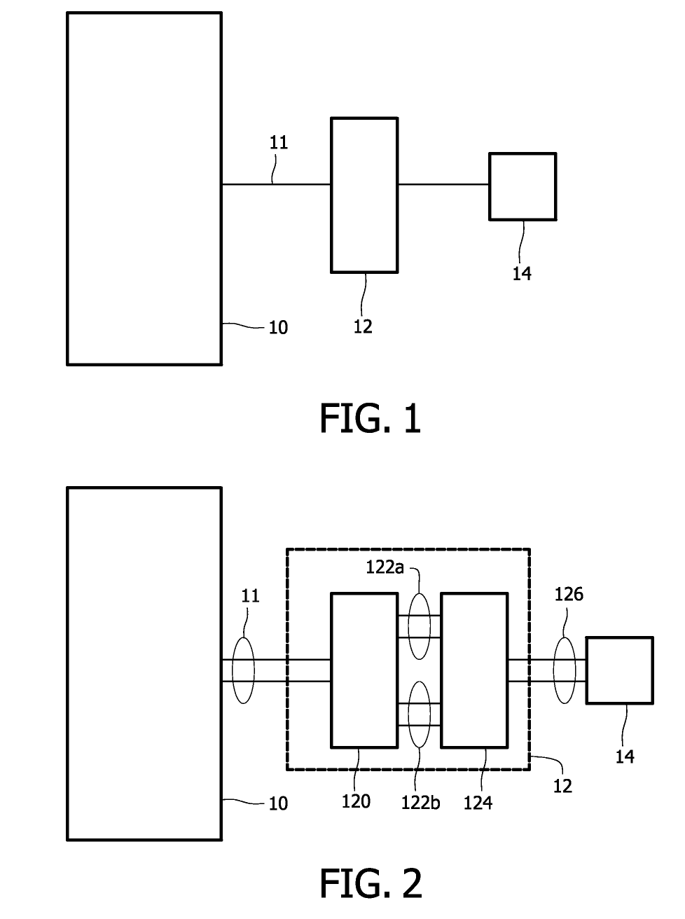

FIG. 1 shows a circuit wherein a composite delay component is realized by re-using a basic delay.

FIG. 2 shows a handshake implementation of a composite delay circuit.

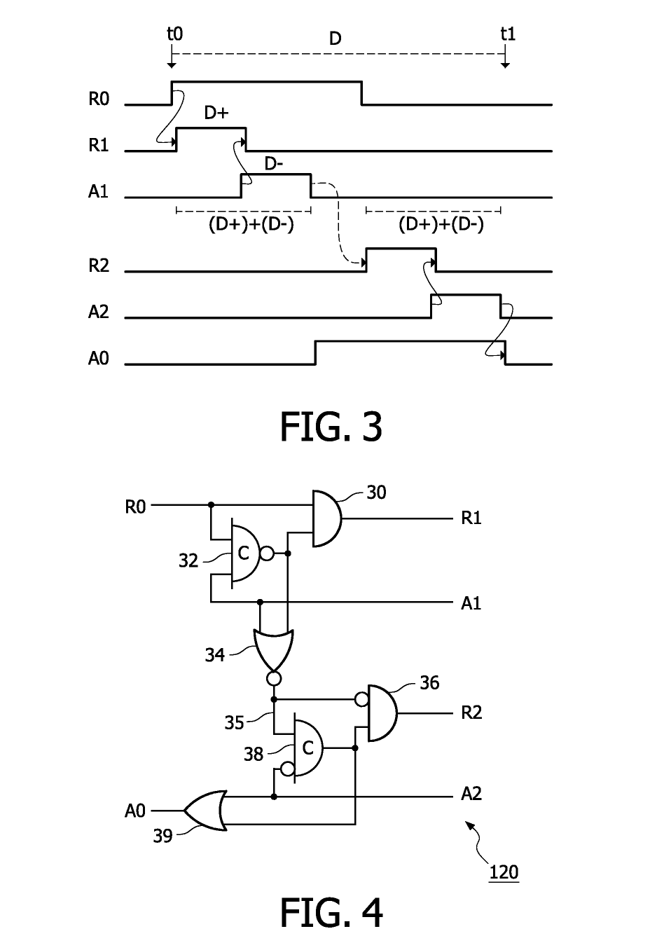

FIG. 3 shows a timing diagram of operation of the circuit

FIG. 4 shows a sequencing circuit

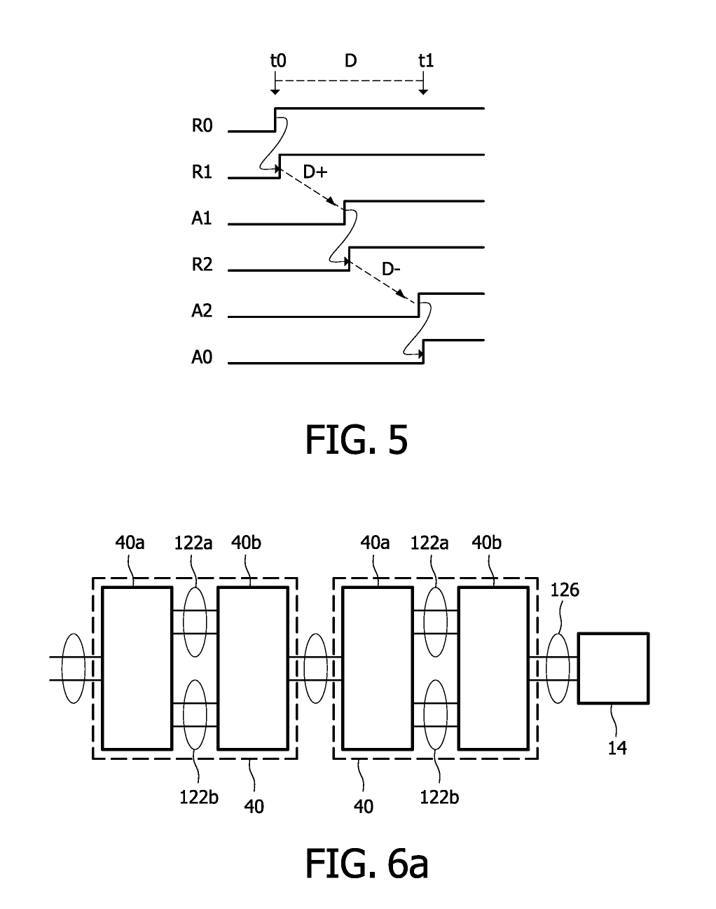

FIG. 5 shows an alternative timing diagram

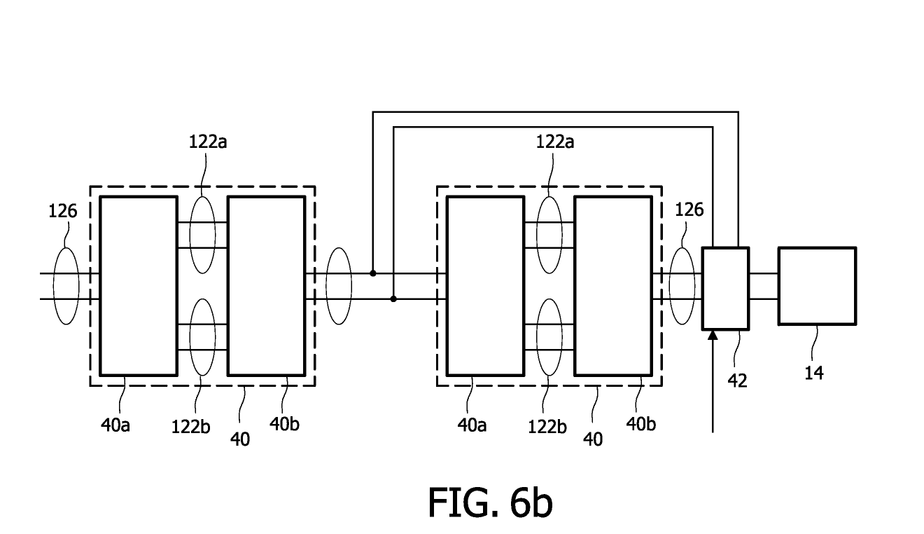

FIGS. 6, 6b show chained delay circuits

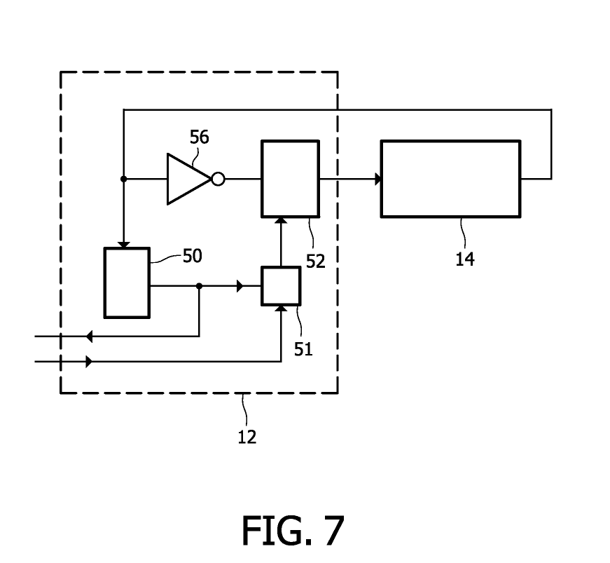

FIG. 7 shows a delay circuit with an oscillator loop

FIG. 1 shows a circuit structure for realizing an asynchronous delay. The circuit contains a data processing circuit 10, a delay repetition circuit 12 and a delay circuit 14. Data processing circuit 10 has a handshake interface 11 coupled to delay repetition circuit 12, which in turn has a handshake interface to delay circuit 14. In operation, the delay repetition circuit 12 receives a request signal from data processing circuit 10 and in response causes a series of signals to pass through delay circuit 14, the first signal starting in response to the request and each subsequent signal starting after a preceding one of the signals has passed through delay circuit 14. Once a predetermined number of signals has passed through delay circuit 14 delay repetition circuit 12 returns an acknowledge signal to data processing circuit as a response to the original request signal.

The term “handshake interface” for the interfaces between the different circuit covers any type of connection for exchanging signals that indicate a request and an acknowledgement of that request, combined with a definition of request and acknowledge signals. A standard example is a four phase handshake interface, which comprises two conductors, one conductor being used to raise a voltage as a request signal and the other conductor being used to raise a voltage as an acknowledge signal, followed by successive lowering of the voltages to complete the handshake. Generally, use of a handshake interface implies that the interfaced circuits are constructed so that normally no new request will be generated before an acknowledgement has been received in response to the previous request and no new acknowledgement will be generated until a new request has been received. In the case of a four phase handshake interface, moreover, the circuits are constructed so that normally the voltage on the request conductor is not lowered before the voltage on the acknowledge conductor is raised and the latter is not lowered before the voltage on the request conductor is lowered.

Another example of a handshake interface is a two-phase handshake interface, also with two conductors, but wherein the request and acknowledge signals involve a change from a preceding logic level without return to that logic level. A further example is a single conductor interface, wherein requests are indicated by pulling up the voltage on the conductor from one side and acknowledgements by pulling down the voltage from the other side.

Because delay repetition circuit 12 ensures that delay circuit 14 must pass a plurality of successive signals before delay repetition circuit 12 responds to data processing circuit 10 a delay circuit 14 for a small delay can be used to generate a much longer delay. Various implementations for delay repetition circuit 12 will be described.

FIG. 2 shows an embodiment wherein an asynchronous delay is realized by means of further handshake interfaces. Delay repetition circuit 12 comprises a sequencer circuit 120 and a handshake multiplexer circuit 124. Sequencer circuit 120 has a passive handshake terminal coupled to handshake interface 11 and active handshake terminals 122a,b coupled to passive handshake terminals of handshake multiplexer circuit 124. Handshake multiplexer circuit 124 has a request output coupled to an input of delay circuit 14 and an acknowledge input coupled to an output of delay circuit 14.

In operation data processing circuit 10 performs a data processing function (the exact nature of which is not relevant to the invention). At some stage during performance of this function data processing circuit generates a request signal to delay repetition circuit 12 at handshake interface 11 and receives back an acknowledge signal after a delay.

FIG. 3 illustrates the timing of this handshake. The figure shows traces for the request signal R0 from data processing circuit 10, a first request signal R1 signal from sequencer 120 at a first handshake terminal 122a, a corresponding first acknowledgement signal A1 at the first handshake terminal 122a, a second request signal R1 signal from sequencer 120 at a second handshake terminal 122b, a corresponding acknowledgement signal A1 at second handshake terminal 122a, and an acknowledgement signal A0 from sequencer 120 back to data processing circuit.

At a first time point to data processing circuit 10 raises the request signal R0. In response sequencer 120 raises the request signal R1 at first handshake terminal 122a. Handshake multiplexer 124 passes this request signal to delay circuit 128. After a delay interval D+delay circuit 14, in turn, passes this signal as an acknowledgement back to handshake multiplexer 124, which transmits the acknowledgment back as acknowledgement signal A1 to the handshake terminal 122a that issued the corresponding request.

Thereupon sequencer 120 lowers the request signal R1 at first handshake terminal 122a. In response handshake multiplexer 124 also lowers the request signal to delay circuit 128. After a delay interval D− delay circuit 14, in turn, lowers it output signal. (Here D+ and D− are the delay times of responses to positive and negative transitions respectively. Preferably, the circuit is designed so that these delay times are equal, but in practice differences may exist). In response handshake multiplexer 124 lowers the acknowledgement signal A1 to the handshake terminal 122a. Subsequently, the sequencer raises acknowledge signal A0 in interface 11. Note that this transition occurs after a delay of D+plus D− (twice the basic delays when D+ and D− are equal) after the rising transition in signal R0.

Subsequently sequencer 120 waits for a falling transition in R0 and then repeats the whole sequence at its second handshake terminal 122b. Sequencer 120 raises the request signal R2 at second handshake terminal 122b. Handshake multiplexer 124 passes this request signal to delay circuit 128. After a delay interval D+delay circuit 14, in turn, passes this signal as an acknowledgement back to handshake multiplexer 124, which transmits the acknowledgment back as acknowledgement signal A2 to the handshake terminal 122b that issued the corresponding request. Thereupon sequencer 120 lowers the request signal R2, handshake multiplexer 124 lowers the request signal to delay circuit 128. After a delay interval D− delay circuit 14, in turn, lowers it output signal. In response handshake multiplexer 124 lowers the acknowledgement signal A2 to the second handshake terminal 122b.

In response to the lowering of the acknowledgement signal A2 at the second handshake terminal 122b sequencer 120 lowers the acknowledge signal A0 to data processing circuit 10. The delay from original time point t0 to the time-point t1 at which the acknowledge signal A0 to data processing circuit 10 is lowered defines the overall delay of the handshake. The overall delay contains twice the delay D+plus D− which is the delay that is normally introduced by delay circuit 128.

It may be noted that in this implementation a sequencer 120 has been used that raises the acknowledge signal A0 to data processing circuit 10 in response to the fall of the acknowledge signal A1 at its first handshake terminal 122a. Similarly, sequencer 120 raises the request signal R1 at its second handshake terminal 122b in response to the fall of the request signal R0 from data processing circuit 10. Thus sequencer 120 realizes a delay D+plus D− before raising the acknowledgement signal to data processing circuit 10 after the rise of the request signal from data processing circuit 10. Similarly, sequencer 120 realizes this delay D+plus D− before lowering the acknowledgement signal to data processing circuit 10 after the lowering of the request signal from data processing circuit 10.

As a result each transition in input signal R0 is delayed for a doubled delay period before the transition is returned at output signal A0. In practice the overall delay will be slightly larger due to internal delays in repetition circuit 12.

FIG. 4 shows an embodiment of such a sequencer circuit 120, comprising AND gates 30, 36, OR gates 34, 39 and C-elements 32, 38 (inversions are indicated by circles). C-elements are conventional component circuits for asynchronous circuit design. Basically, these are set/reset latch circuits that are set when both their inputs are high and reset when both input are low (subject to inversions as indicated). The circuit contains two circuit parts, connected by a node 35. The first circuit part (30, 32, 34) is arranged to raise the logic level at node 35 once a handshake R1/A1 has been completed and to lower the logic level at node 35 once request signal R0 has been lowered. The second circuit part (36, 38, 39) is arranged to raise acknowledge signal A0 once the logic level at node 35 has been raised, to start a handshake R2/A2 once the logic level at node 35 is lowered and to lower acknowledge signal A0 once this handshake A1/R1 has been completed. Although not shown, reset inputs may be needed to reset the C-elements initially (to logic low).

It should be realized that implementations of handshake components that implement the behavior of the sequencer, multiplexer and delay circuit are known per se. The multiplexer, for example may contain an OR gate to generate the request signal to the delay circuit 14 from the request signals at its inputs and C-elements to raise and lower its acknowledgement outputs when its corresponding request input is high and low respectively together with its acknowledgement input. Different, equivalent implementations exist and any may be used to realize the described signals.

It should be realized that the signals used in the example only represent signals for an example of an implementation of the circuit. Different implementations are possible and these may lead to different signal combinations. For example, equivalent handshakes can be implemented in many ways, e.g. other implementations may use inverted versions of the signals for the signals, or for part of the signals. Furthermore, in the particular implementation that leads to the signals of FIG. 3, four-phase handshake signalling has been used for all components (wherein a handshake involves assertion of request and acknowledge signals as well as their return to their original values).

FIG. 5 shows alternative signalling, wherein a two-phase protocol is used, wherein only a single signal edge is used to signal a request or an acknowledge. These signals implement the same abstract combination of handshakes the signals of FIG. 2, with a delay of D+plus D−, because two handshakes pass through delay circuit 128. In a two-phase implementation, the request and acknowledge signals do not return to their original levels in one handshake exchange. In a next subsequent handshake exchange transitions in the opposite direction will be used to signal request and acknowledge signals, so that after that handshake the signals return to their original levels.

However, the implementation of a handshake multiplexer for a two-phase handshake protocol is typically more complex than that for a four phase handshake protocol. Therefore it is advantageous to use four phase handshake signals at least at the handshake interfaces between sequencer 120 and handshake multiplexer 124.

It may also be noted that in the four-phase protocol there is a freedom of implementation choice for the timing of part of the signal transitions. For example, in other implementations sequencer 120 may raise the request signal R2 at its second handshake terminal 122b in response to completion of the handshake at its first handshake terminal 122a, and raise the acknowledge signal A0, after completion of the handshake at second handshake terminal 122a, thus creating a delay of twice D+plus D− between the rise in the request R0 signal and the rise in the acknowledgement signal A0. In this case sequencer 120 responds to the lowering of request signal R0 by lowering the acknowledge signal A0 without delay. This type of circuit may be used in applications where symmetry in the delays to rising transitions of the request and falling transitions is not required. Conversely in another implementation example sequencer 120 may raise the acknowledgement signal without delay in response to the rise of request R1 signal, and delay in lowering the acknowledge signal.

Although the invention has been described in terms of a circuit that contains a two-output sequencer coupled to a two input handshake multiplexer, it should be understood that a sequencer with more outputs may be used, coupled to a handshake multiplexer with more inputs, so that a greater number of delays of the delay circuit will occur before the handshake is completed. The same effect can be realized by chaining a plurality of combinations of a sequencer and a multiplexing circuit.

FIG. 6 shows a circuit with a plurality of combinations 40 of a sequencer 40a and a multiplexing circuit 40b between the input interface and delay circuit. Any number of combinations may be chained in this way, leading to a delay that grows exponentially with the number of combinations. Effectively, the circuit could be regarded as a circuit with a composite delay circuit, wherein the composite delay circuit is a handshake chain of a sequencer, a handshake multiplexing circuit and either a basic delay circuit, or another composite delay circuit.

FIG. 7 shows a further implementation of a delay circuit. This circuit contains a counter circuit 50, an exclusive OR gate 51 and an oscillator loop that comprises an enable circuit 52, the delay circuit 14 and an inverter 56 (although separate circuits are shown it should be realized that the inverter, delay and/or enable function may be combined in a circuit). Exclusive OR gate 51 has inputs coupled to an overall input of the overall delay circuit and to an output of counter circuit 50. Exclusive OR gate 51 has an output coupled to a control input of enable circuit 52. An output of delay circuit 54 is coupled to a clock input of counter circuit 50. The output of counter circuit 50 is an overall output of the overall delay circuit. Counter circuit 50 is arranged to toggle its output signal each time after counting N clock transitions.

In operation a signal transition at the overall input causes the oscillator circuit loop to be enabled until it has produced N clock pulses, which is signalled by counter circuit 50. To ensure that no new transition has entered delay circuit 14 when the oscillator loop is disabled, the disable signal from 51 has to arrive at enable circuit 52 before the last of the N clock signals. Therefore, the signal driving counter 50 is delayed for a period that matches the delays of 50 and 51 before it enters enable circuit 52. In the embodiment of FIG. 7 it is assumed that the delay of inverter 56 ensures this. If not an additional delay circuit may be added in series with inverter 56 (or replace inverter 56 if the inversion on the loop is realized in another way).

However, it should be realized that there are other ways of handling this problem. For example if it is guaranteed that signal transitions at the overall output will be followed by a transition at the overall input only after sufficient delay, counter circuit 50 may have its input coupled to the output of enable circuit 52. A circuit may be included to impose such a delay, for example by delaying the acknowledge signal or subsequent request signals for the time needed to pass a transition through delay circuit 14. In the circuit of FIG. 7 transitions of both polarities at the overall input cause enabling of the oscillator loop. Hence the circuit has a symmetric behaviour: it responds to both rising and falling transitions substantially after N times the delay of delay circuit 14.

It should be realized that alternative implementations are possible, wherein the oscillator loop is controlled with the same effect. For example, exclusive or circuit 51 and counter circuit 50 may be replaced by any state machine with the behaviour of making a transition to a first state in response to a request signal, enabling the oscillator loop from the first state, making N transitions in response to N clock pulses until a state is reached wherein the state machine disables the loop and then returns an acknowledgement of the request signal. The most efficient implementation of such a state machine involves a counter. As another example, instead of a synchronous counter circuit a chain of counters may be used.

Although it is desirable in many applications that the circuit responds symmetrically to transitions of mutually opposite polarity, this may not be needed for all applications. In other applications, therefore, the circuit may be arranged to respond to one type of transition after the oscillator has produces N pulses, and directly, or after a different number of pulses after another type of transition.

It should be realized that the implementation of FIG. 7 requires that the delay of the internal delay circuit is larger than the worst case settling time of counter circuit 50. The handshake implementations do not suffer from this problem. However, in the oscillator loop this problem can be solved by pipelining of counter circuit 50 for example.

It will be appreciated that in each implementation the total delay time of the circuit is determined by an integer multiple of the delay time of the basic delay circuit 54. The circuits can be designed so that a predetermined integer multiple is realized, but alternatively a programmable integer multiple may be supported. For example, counter circuit 50 may be provided with a control input for controlling the number of states that control circuit will pass through before toggling, or a bypass circuit 42 (e.g. containing a multiplexer and a de-multiplexer (not shown)) could be used to selectively bypass a combination (40) of a sequencer and a handshake multiplexing circuit in the circuit of FIG. 6 (as shown in FIG. 6b). As another example, programming can be effected by adding one or more handshake short circuit circuits (not shown) each in a respective one of the handshake interfaces (122a,b). These short circuit circuits are arranged for selectably (under control of programmed information) either passing handshake signals normally, or “short-circuiting” the sequenced handshake interfaces (122a,b) in which they are inserted, i.e. acknowledging handshakes at these interfaces without waiting the delay through the delay circuit (14), or forwarding a request.

1. An electronic circuit wherein an asynchronous delay is realized, the circuit comprising
a delay circuit (14);
a control circuit (12) with an input for receiving a start signal and an output for supplying a response, the control circuit (12) being arranged to cause a series of signals to be passed through the delay circuit (14), the series starting at a time that is time-continuously triggered by the start signal, each successive signal in the series starting after a preceding signal has emerged from the delay circuit (14), the series being terminated after a controlled number of more than one signal has been passed, the control circuit (12) supplying the response upon termination of the series.

2. An electronic circuit according to claim 1, wherein the control circuit (12) is arranged to respond to transitions of mutually opposite polarity in the start signal each by causing a respective series of pulses to be passed through the delay circuit (14), and to supply responses to the transitions upon termination of the respective series.

3. An electronic circuit according to claim 1, wherein the input and the output of the control circuit (12) form a first handshake interface (11) and an input and an output of the delay circuit (14) form a second handshake interface (126), the control circuit (12) comprising a handshake sequencer circuit (120) and a handshake multiplexer circuit (124), coupled in series between the first and second handshake interface (11, 126), the handshake sequencer circuit (120) having mutually sequenced interfaces (122a,b) coupled to respective interfaces of the handshake multiplexer (124), so that successive sequenced handshakes on respective ones of the sequenced interfaces (112a,b) each lead to a respective handshake at the second handshake interface (126) that is acknowledged via the delay circuit (14).

4. An electronic circuit according to claim 3, wherein the sequencer circuit (120) is arranged to start a first handshake on a first one of the sequenced interfaces (122a) in response to a assertion of request signal from the first handshake interface (11) and to assert an acknowledge signal on the first handshake interface (11) in response to completion of the first handshake and to start a second handshake on a second one of the sequenced interfaces (112b) in response to de-assertion of the request signal from the first handshake interface (11) and to de-assert the acknowledge signal on the first handshake interface (11) in response to completion of the second handshake.

5. An electronic circuit according to claim 3, comprising a plurality of combinations (40), each of a respective sequencer circuit (40a) with sequenced handshake interfaces (122a,b) and a respective handshake multiplexer (40b) coupled to the sequenced handshake interfaces (122a,b), the combinations (40) being coupled in series between the first and second handshake interface (11, 126).

6. An electronic circuit according to claim 1, wherein the control circuit is arranged to make the controlled number programmable.

7. An electronic circuit according to claim 6, wherein the input and the output of the control circuit (12) form a first handshake interface (11) and an input and an output of the delay circuit (14) form a second handshake interface, the electronic circuit comprising
a plurality of combinations (40), each of a respective sequencer circuit (40a) with sequenced handshake interfaces (122a,b) and a respective handshake multiplexer (40b) coupled to the sequenced handshake interfaces (122a,b), the combinations (40) being coupled in series between the first and second handshake interface (11, 126);
at least one bypass circuit (42) for selectably bypassing at least one of the combinations (40).

8. An electronic circuit according to claim 6, wherein the input and the output of the control circuit (12) form a first handshake interface (11) and an input and an output of the delay circuit (12) form a second handshake interface (126), the electronic circuit comprising
a plurality of combinations (40), each of a respective sequencer circuit (40a) with sequenced handshake interfaces (122a,b) and a respective handshake multiplexer (40b) coupled to the sequenced handshake interfaces (122a,b), the combinations (40) being coupled in series between the first and second handshake interface (11, 126);
at least one handshake short circuiting circuit, for selectably handling a handshake from one of the sequenced handshake interfaces (122a,b) without causing any handshake to be passed through the delay circuit (14).

9. An electronic circuit according to claim 1, comprising an oscillator loop (56, 52, 14) that contains the delay circuit (14) and an enable circuit (52), the control circuit (12) being arranged to enable the oscillator loop (56, 52, 14) in response to the start signal temporarily until the oscillator loop (56, 52, 14) has generated a predetermined number of signals, and to supply the response when the predetermined number of signals has been generated.

10. An electronic according to claim 2, comprising an oscillator loop (56, 52, 14) that contains the delay circuit (14) and an enable circuit (52), the control circuit (12) being arranged to enable the oscillator loop (56, 52, 14) in response both to transitions of mutually opposite polarity in the start signal, in each case temporarily until the oscillator loop (56, 52, 14) has generated a predetermined number of signals and to supply respective responses to the transitions when the predetermined number of signals has been generated.

11. A method of asynchronously generating a delayed response signal in response to a start signal, the method comprising
supplying the start signal;
causing a series of signals to be passed through a delay circuit (14),
first starting a first signal of the series at a time that is time-continuously triggered by the start signal,
subsequently starting each successive signal in the series after a preceding signal has emerged from the delay circuit (14),
terminating the series after a controlled number of more than one signal has been passed,
supplying the response signal upon termination of the series.
